(19) United States
(12) Patent Application Publication
(10) Pub. No.: US 2025/0187270 A1
(43) Pub. Date: Jun. 12, 2025

(54) METHOD FOR CONTROLLING PROCESSES ON PLASTICS-PROCESSING MACHINES

(71) Applicant: ARBURG GMBH + CO KG, Loßburg (DE)

(72) Inventors: Werner FAULHABER, Lossburg Wittendorf (DE); Jürgen PETERS, Schiltach (DE)

(21) Appl. No.: 18/835,165

(22) PCT Filed: Jan. 20, 2023
(86) PCT No.: PCT/EP2023/051366

§ 371 Date: Aug. 1, 2024

(30) Foreign Application Priority Data
Feb. 7, 2022 (DE) 10 2022 102 748.1

(51) Int. Cl. B29C 64/386; B29C 45/76; B33Y 50/00; G06F 30/20

(52) U.S. Cl. CPC B29C 64/386; B29C 45/7693; B33Y 50/00; G06F 30/20; B29C 2945/76976

(57) ABSTRACT

A method for controlling processes on at least one plastics-processing machine. The method comprises the following steps:-performing a simulation so as to produce at least one component with generation of simulation datasets (SD) that relate to an outline of the component and/or material properties,-determining a process image so as to operate the machine at an idealized operating point based on the simulation datasets (SD),-generating a design of experiments (DoE) matrix,-iteratively simulating the DoE matrix with computing of remaining variations of process parameters while reducing the DoE matrix and obtaining a trained process model for the machine, using which a component is able to be produced on the machine,-verifying the remaining variations of process parameters through real tests (40), in which components are produced on the machine and assessed, so as to generate a process parameter dataset (PPD) for subsequent operation of the machine at an operating point (AP), by virtue of an operator communicating interactively with a software communication robot, in particular chatbot, and the method steps comprise at least two artificial intelligences that interact

### REFERENCE TO RELATED APPLICATIONS

The present application relates to and claims the priority of German patent application 2022 102 748.1, filed on Feb. 7, 2022, the disclosure of which is hereby expressly, in its entirety, made part of the subject matter of the present application.

### TECHNICAL FIELD

The disclosure relates to a computer-implemented method for controlling processes on at least one machine for processing plastics and other plastifiable materials and to an associated machine controller for carrying out the method, as well as to a computer program product for carrying out the method.

Before the prior art and the disclosure proceeding therefrom are discussed in greater detail below, the terms used in the context of this application will first be defined.

When the term “component” is used in the context of this application, this is not intended to be restrictive, as the method can also be used in multi-component injection moulding, multi-cavity injection moulding, injection moulding with so-called family moulds or known special methods or also in additive manufacturing. In all these cases, components, items and objects are produced for which the term “component” is used synonymously.

When the term “process parameters” is used in the context of this application, it refers to the parameters required for the manufacture of components on plastics processing machines with which such machines manufacture components. As a rule, these parameters are in particular pressure, path of a conveying means, temperature, speed, filling volume, discharge volume, droplet size and the like.

Accordingly, a process parameter dataset is the set of all process parameters required to describe such a plastics processing machine for the production of components.

When the term “expert knowledge” is used in this application, it refers to the knowledge that is available to an experienced operator of such a machine. This can be present or liquid knowledge, but expert knowledge also includes non-liquid knowledge that is accessible, for example, from specialised literature. In particular, this knowledge is also based on knowledge of the sequences and interrelationships of the components involved in the processes running on these machines and their interaction with each other. This expert knowledge also includes, for example, knowledge about the respective machines and their machine data or their structure as well as knowledge about materials and their properties. The expert knowledge enables a trained user to commission such a machine at least to the extent that a component can be manufactured and the machine is operational. However, expert knowledge also includes everything that is required to produce high-quality components.

When reference is made to a “process model” and “process image” in the context of this application, what is meant is a virtual model or image of a process that is actually possible on the machine, i.e. of the method for manufacturing components. A process model is generally a dataset that virtually depicts the process that is possible in reality. A “base model” is an initial process model.

A “process window” is a part of such a process model within which the machine for processing plastics and other plastifiable materials can be operated in an operable state with corresponding process parameters or process parameter datasets.

In the context of this application, the term “operating point” means a point that is set using a process parameter dataset on the machine for the manufacture of objects. At this operating point, the machine should be working operationally.

When the term “AI model” is used in this application, it refers to a model of a process or sequence created using artificial intelligence (AI).

### BACKGROUND

The requirements for plastics components and plastics-like components, e.g. in the automotive sector, are becoming increasingly demanding. Issues such as lightweight construction, recyclability and design requirements are leading to ever more complex mould technology and automation and therefore to ever more demanding processes. At the same time, the general shortage of skilled labour is making it increasingly difficult to recruit suitable operating personnel for complex machines, systems and processes. The issue of sustainability is leading to the use of recycled material, which, for example, in the form of unsorted mixtures, has different, non-reproducible properties as compared to a so-called “virgin” material. These fluctuating properties of the plastics mean that processes have to be adjusted and adapted during operation.

Rule-based methods reach their limits with this complexity. It is also not always possible to evaluate the component quality based on the process changes using the machine's internal sensors. What constitutes a so-called “good part” is ultimately determined by the requirements placed on the component. Parameters such as dimensional accuracy, warpage, sink marks, overmoulding, gaps, surface quality, colour, weight, etc. are just some of the aspects that determine the quality and usability of the plastics product.

Methods are known in which the filling pattern and the flow front progression from the so-called injection point can be simulated in so-called filling simulations for a specific plastics material or a material of a specific plastics class as early as the injection mould construction stage. Such a method is known, for example, from DE 10 2015 107 025 B4.

Methods are also known, for example from WO 2020/058387 A1, in which these filling simulations are supplemented by machine-specific algorithms from which parameters, e.g. speed, pressure and temperature profiles, can be derived for the workshop programming of an injection moulding machine. This filling simulation, extended to include the machine influences, can be stored as a model for exactly one operating point. As a rule, a demouldable component can be produced when the injection mould is first commissioned and mould damage can be avoided.

Alternatively, the operator can slowly approach the complete filling of the mould cavity and thus adjust the process. It is ideal to then use a so-called Design of Experiments (DoE) method to determine the process limits and the dependencies of machine/process parameters on the component quality. For example, the question may be how the component changes if the holding pressure profile is increased by 5%. How does the component change if the switchover point from injection to holding pressure is shifted? From this, a rule-based work instruction can be derived for the operator or, in the next step, an automatic adjustment of process values can be carried out. If this problem occurs, then try to bring the process and thus the product back into the range of good component quality by manually or automatically changing parameter A (the process optimises itself in the event of fluctuations).

As already described, rule-based methods are reaching their limits more and more quickly due to the complexity.

Various possibilities for machine learning and interactive communication are known in the field of so-called “artificial intelligence”:

DE 10 2020 111 128 A1 describes a machine learning process and a monitoring system for additive manufacturing.

Learning units that work together with the machines are also known, for example from DE 10 2017 006 703 A1, which discloses a machine learning device that trains a current command for a motor.

An automatic and adaptive production method in which a robot learns the position and orientation of other elements in a robot production process based on geometric relationships can be found in DE 11 2016 002 431 T5.

Software communication robots, also known as chatbots, are used for interactive contact with robots of this kind and make contact with an operator via text and/or speech recognition (see WO 2020/020515 A1).

US 2021/362242 A1 discloses a rapid material development process for a powder bed fusion additive manufacturing (PBF AM) process that generally uses a computational fluid dynamics

(CFD) simulation to facilitate the selection of a simulated parameter set that can then be used in a design of experiments (DoE) to predict an orthogonal parameter space with an ideal parameter set. The orthogonal parameter space defined by the DoE can then be used to generate a plurality of reduced volume build samples (sections of build samples) using PBF AM with varying laser or electron beam parameters and/or raw material chemistries. The reduced volume build samples are mechanically characterised and analysed using high-throughput techniques, such as X-ray tomography, to provide an optimal parameter set for a 3D article or validation sample, allowing a better understanding of the parameters and their effects on defects and microstructure. In addition, machine learning techniques (artificial intelligence) can be used to optimise future parameter selection by modelling the relationship between input processing parameters and material characterisation outputs. The machine learning techniques are used in simulations and design of experiments.

DE 10 2017 130 997 A1 discloses a method for simulating a shaping process or a sub-process of the shaping process, wherein states of objects involved in the shaping process, in particular a shaping machine, a shaping tool and/or a material to be processed, are calculated in discrete and successive time steps while specifying conditions. The conditions represent input parameters of the shaping process, wherein (a) after a time step which lies before the end of the simulated shaping process or the sub-process of the shaping process, a check of the calculated states of the objects involved in the shaping process is carried out using at least one quality criterion. If (b) the check after step (a) shows that the at least one quality criterion is not fulfilled, at least one of the following steps is carried out: resumption of the simulation with repeated calculation of the time step and/or a preceding time step; continuation of the simulation with calculation of a time step following the time step, (c) wherein the conditions are at least partially changed during the execution of method step (b). Interaction with an operator is possible by means of an interface. The process uses also artificial intelligence during the simulation to enable an optimised manufacturing process.

A method for simulating a process for filling a mould and ejecting a part from a mould cavity using ejector pins is known from US 9 138 929 B2. The method comprises: simulating a process for filling a mould by: providing a three-dimensional computer model defining a geometry of a solution domain, setting boundary conditions, discretising the solution domain based on the model to form a mesh having a plurality of cells, appending physical data for materials, solving energy and flow equations for at least a portion of the solution domain, calculating flow and temperature conditions in the cells as a function of time to obtain results of the mould filling simulation. The method further comprises providing an ejection simulation that simulates the process of ejecting the simulated part from the mould cavity by: accepting user inputs via a user interface to define: a number of ejector pins, a placement of the ejector pins, a geometry of the ejector pins, and a speed at which the ejector pins move. Furthermore, the method comprises using results of the mould filling simulation as starting conditions for the ejection simulation, solving static equilibrium equations for at least a part of the solution domain and calculating effects of the ejection process on the simulated part based on: the number of ejector pins, the placement of the ejector pins, the geometry of the ejector pins and the speed at which the ejector pins move. The method does not include the production of a real part and its evaluation by an operator, nor does it include interactive communication in which the operator can mark parts of a three-dimensional representation.

### BRIEF SUMMARY

The disclosure is to enable even a semi-skilled operator with little experience to quickly achieve a machine setting with which “good parts” can be manufactured.

A computer-implemented method is used here to control processes on at least one machine for processing plastics and other plastifiable materials. Firstly, a simulation for manufacturing at least one component is carried out on the machine, generating simulation datasets, or corresponding datasets are read in additionally or alternatively. These simulation datasets contain the simulations required for manufacturing the component, wherein these datasets relate at least to a mould contour of the component and/or material properties of the at least one material to be processed for manufacturing the component.

These simulation datasets can be used to create a process image for operating the machine with an idealised operating point. This process image developed by artificial intelligence through a large number of simulations can be used as a base model so to speak for virtual operation of the machine.

The basic artificial intelligence model is then further trained and verified using statistical test series, which are summarised in a so-called “design of experiment” (DoE) matrix. The statistical test planning with the DoE matrix results in a set of possible combinations of parameter values for operating the machine. By iteratively simulating the DoE matrix, remaining variations of process parameters are determined with which the machine can be operated in reality. This already leads to a reduction in the possible combination of parameter values. The original base model thus becomes a trained process model for the machine.

In the next step, the remaining variations of process parameters after the simulation of the DoE matrix are verified by carrying out real tests. Here, the components produced on the machine are evaluated by the operator communicating with a software communication robot, in particular a chatbot, which recognises text and/or voice input and/or gesture input by the operator and can also output text and/or voice messages and/or gestures to the operator accordingly. Other visual and auditory communication paths are also included in the case of operator-machine communication, as well as a path via other perception channels such as kinaesthetic, olfactory or gustatory. The steps of the method described above comprise at least two artificial intelligences that interact with each other.

As a result, this leads to a process parameter dataset for and at a working point at which the machine can produce components that are rated as good. The advantage of this approach is that by using at least two artificial intelligences, the variety of possible process parameter datasets is reduced to a reasonable range. Even a semi-skilled operator can quickly reach a working point at which the machine produces high-quality components by communicating with the software communication robot, e.g. a chatbot.

At the same time, however, a process model is also created that ensures the continued operation of the machine in an advantageous manner. If, for example, there are deviations due to changes in the batch of material, the machine can initially make changes automatically within a certain range using the existing process model and continue to manufacture components. At the same time, the prerequisites are created for the machine or artificial intelligence to contact the operator as required if the process model is left.

The aim of the development is to develop a basic AI model of the process through a large number of simulations and to further train and verify it through statistical test series (DoE). The new AI process model optimised from this is linked to another, second AI model, a software communication robot, in particular a chatbot. Here, the current component quality is reported back to the AI process model in dialogue with the operator using a simple method, preferably by means of a 3D image of the plastics component and graphically supported. The at least two AI models interact with each other and the quality of the model can be further developed during operation by way of machine learning.

Preferably, in the step in which the variations of process parameters are verified by carrying out real tests, an automated dialogue takes place with a control device that communicates with at least one evaluation system for evaluating the component in order to further optimise the process.

The method is preferably carried out on an injection moulding machine or on a machine for the additive manufacturing of components. These are precisely the machines on which the use of recycled materials or the increasing complexity of components make it necessary to respond quickly and efficiently to changing conditions in the field of plastics processing machines.

A wide variety of process simulations can be considered as simulations from which the simulation datasets are created. These can, for example, be processes that take into account the interaction between the injection moulding unit and the mould closing unit, e.g. in conjunction with the injection and holding pressure phases. A particularly preferred embodiment has proven to be the use of a filling simulation for the filling of a mould cavity of an injection mould on an injection moulding machine as a simulation for the production of the at least one component on the machine, since the filling simulation reflects well the problems in the manufacturing of components.

Preferably, to generate the Design of Experiments (DoE) matrix, the artificial intelligence can access expert knowledge in which various pieces of information are categorised by class. These classes can be, for example:
classes of machine properties,
classes of material properties,
component classes,
tool classes for injection moulding tools,
filling time classes in the injection process for manufacturing the component,
flow path to wall thickness ratios in the component,
plastics classes,
material classes.

Preferably, these criteria are used for classification in collaboration with artificial intelligence in order to retrieve relevant information from the expert knowledge for the calculation and make it available to the operator. This has the advantage that the information that is important for production can be extracted quickly and reliably from the expert knowledge together with the operator and made available for further use.

Preferably, the process parameter dataset is calculated taking into account material information that can be specified by the operator and/or selected from expert knowledge. With this material information, the process model can be quickly honed so that even sudden material fluctuations can be dealt with in such a way that high-quality components can be manufactured.

In order to advantageously simplify the assessments by the operator as part of the interactive communication with the software communication robot, the component can preferably be displayed three-dimensionally on a display unit so that the operator can mark points in the component display for the software communication robot that are of significance. It may be important, for example, if sink marks or poor surface quality are recognisable on the component or if dimensional accuracy is not guaranteed. Other evaluation criteria are known to a person skilled in the art.

With the process parameter dataset obtained, the machine is operated at a working point that is part of a process window. This process window is in turn part of a process model that covers and contains the entire possible working range of the machine. As long as the machine is operated within the process window, it is possible to produce components according to the evaluated process models with good results. For this reason, the process window is also monitored to determine whether it is left during machine operation. This has the advantage of ensuring reliable operation. If the range is left, interactive contact with the operator can either change the setting so that operation is possible in the process window again, or the process window can be adapted to the changed conditions, especially if good parts continue to be produced despite the process window having been left.

Preferably, when the process window is left, the process sequence is repeated starting from the step of generating the Design of Experiments (DoE) matrix, but at the latest starting from the verification of the remaining variations of process parameters by real experiments. The known process sequence allows the process model and thus also the process window to be checked and/or adapted advantageously in a targeted manner.

Preferably, the method is also suitable for being carried out on several machines and thus for forming and analysing clusters, particularly with the same machine configurations, the same processes and/or the same materials to be processed. The increased amount of data obtained in this way can be used to further refine the artificial intelligence process model. The operator of such systems can roll out an algorithm generated in this way from their “model factory” to other production sites and obtain the same high product quality everywhere while protecting their expertise at the same time.

Preferably, algorithms generated in this way can also be made available to the machine manufacturer, at least in part, so that advantageously the base models, i.e. the first process models, can be refined using this type of information.

The disclosure provides also a machine controller for a machine for processing plastics and other plastifiable materials, which is set up, configured and/or constructed to carry out the method.

The disclosure provides also a corresponding computer program product with a program code which is stored on a computer-readable medium and is suitable for carrying out the method.

Further advantages can be found in the further dependent claims and the following description of an exemplary embodiment.

### BRIEF DESCRIPTION OF THE FIGURES

The disclosure is explained in greater detail below with reference to an exemplary embodiment shown in the Figures, in which:

FIG. 1 shows a schematic flow chart of the method,

FIG. 2 shows a diagram of the process elements, and

FIG. 3 shows a diagram of the process extension.

### DETAILED DESCRIPTION

The disclosure will now be explained in greater detail by way of example with reference to the accompanying drawings. However, the exemplary embodiments are only examples and are not intended to limit the inventive concept to a particular arrangement. Before the disclosure is described in detail, it should be pointed out that it is not limited to the respective components of the device and the respective method steps, as these components and methods may vary. The terms used herein are merely intended to describe particular embodiments and are not used in a limiting manner. Furthermore, when the singular or indefinite articles are used in the description or in the claims, this also refers to the plurality of these elements, unless the overall context clearly indicates otherwise.

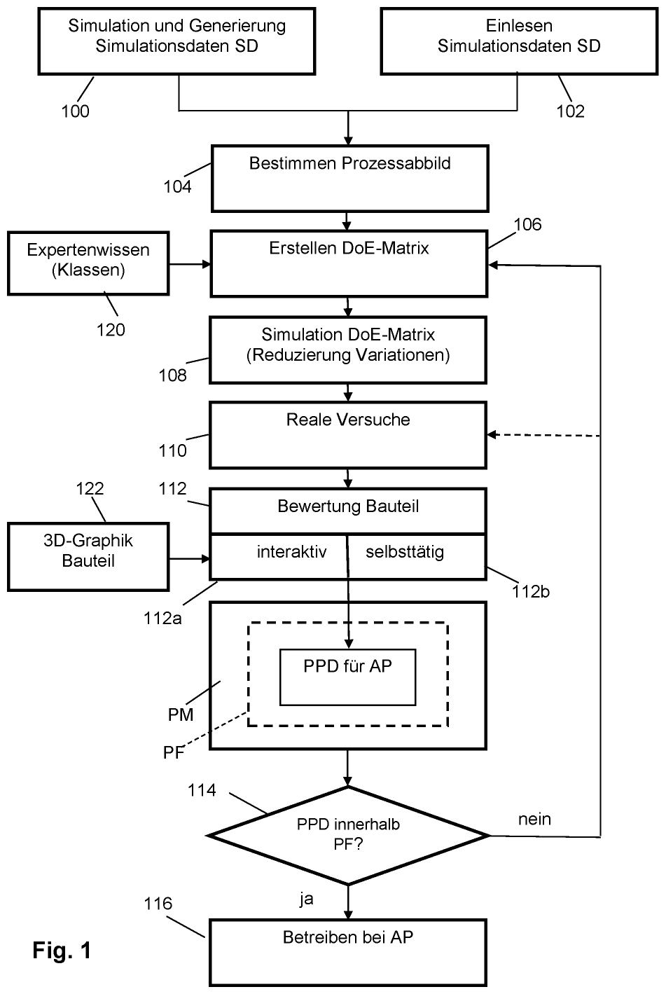

FIG. 1 shows a computer-implemented method for controlling processes on at least one machine for processing plastics and other plastifiable materials. In step 100, a simulation is carried out for producing at least one component on the machine, generating simulation datasets or simulation data SD. Alternatively or additionally, this data can also be read in according to step 102 from simulation datasets or simulation data SD already generated during the production of at least one component on the machine. These simulation datasets contain the simulations required for the production of the component, which are suitable for simulating the process sequence. As a rule, the simulation datasets relate to at least one mould contour of the component and/or material properties of the at least one material to be processed.

The machine is preferably an injection moulding machine for processing plastics and other plastifiable materials or a machine for the additive manufacturing of components, about which information is available, at least in expert knowledge 120, regarding its operation as well as machine data MD in general, but also for the specific machine on which the manufacture of components is to take place. In principle, application to other plastics processing machines is possible.

The construction and operation of such an injection moulding machine for processing plastics and other plastifiable materials, comprising an injection moulding unit and a mould closing unit with a (injection) mould held between mould plates, in the mould cavity of which an injection-moulded part is formed, are known to a person skilled in the art, and therefore this will be discussed below only to the extent necessary for an understanding of the disclosure. The construction and operation of a machine for the additive manufacturing of components, for example by discharging drop-shaped or strand-shaped material for the construction of the component in a construction space, is also known to a person skilled in the art.

If the simulation datasets or simulation data SD are available, a process image for operating the machine with an idealised operating point is determined in step 104. A process image is a virtual image of the process for producing components that actually takes place on the machine.

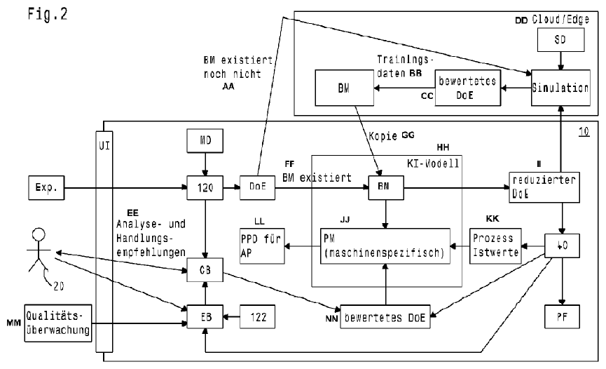

The process image is now used to create a statistical design of experiments (DoE) matrix in step 106, starting from the idealised operating point. In principle, however, it is also possible, as shown in FIG. 2, for the very first DoE matrix to be created solely on the basis of expert knowledge 120. The DoE matrix comprises a set of possible combinations of parameter values for the operation of the machine, for example certain pressure, temperature, speed values or displacement marks or corresponding curves over time, displacement or pressure, which may be required for the operation of the machine.

Once the DoE matrix has been created, another simulation is carried out in step 108 in order to make only those variations of process parameters accessible for further processing with which the machine can also be operated in reality. This is done by iteratively simulating the DoE matrix while calculating and determining the remaining variations of process parameters. This reduces the possible combinations of parameter values in the DoE matrix. At the same time, this leads to a base model BM learnt through the simulation and thus also a process model PM being generated for the machine, with which a component can be produced on the machine.

In the next step 110, the remaining variations of process parameters are now verified by carrying out real tests 40. In these real tests 40, components are produced on the machine and evaluated in step 112 in order to generate a process parameter dataset PPD for operating the machine at an operating point AP.

This is done by involving a second artificial intelligence. Via a software communication robot CB, in particular a chatbot, the operator 20 can communicate interactively with the artificial intelligence in step 112a. The software communication robot CB recognises a voice and/or text input and/or gesture input by an operator 20 and outputs or displays information about the operating state of the machine or the state of the component in voice and/or text and/or gesture form. For this purpose, the software communication robot CB is connected to a control device for data communication in order to control the machine on the basis of the voice and/or text and/or gesture input recognised by the software communication robot CB.

Preferably, the components can alternatively or additionally be evaluated automatically in step 112b by downstream processes by means of an automated dialogue with a control device that communicates with at least one evaluation system for evaluating the component. For example, corresponding automatic scales or optical measuring devices are conceivable.

The result of the evaluation and the previous process sequence is then a process parameter dataset PPD at the operating point AP at which the machine produces good parts as components. The machine is then operated at this operating point AP.

In other words, the process on the machine/system is managed using several AI models generated by ML (machine learning), wherein the number of models is not limited to two. In the following, however, the method is explained using two AI models for the sake of clarity. However, it is conceivable that other AIs could, for example, carry out further simulations to obtain additional data or establish communication with other machines or machine parts in order to further support the desired results of reliable component manufacture.

The first AI model is derived from a filling simulation, for example, as the base model BM. An idealised operating point is also derived from this, for example. Depending on the machine technology, process parameters, supported by AI, are specified on the machine for a DoE process. The model provides meaningful variations of process parameters, depending on the component, the process type, the machine properties and/or the material properties of the material to be processed, e.g. a plastics or a plastics class. Variations within the plastics class are also taken into account here.

This DoE dataset, usually a DoE matrix, is fed back to the simulation directly on the machine or via a digital interface on edge or in the cloud. If the performance of the machine controller 10 on a machine is sufficient, a large number of simulations can be calculated directly from this DoE dataset and simulates the variation of the parameters in different dependencies. The result is an extended process model trained by simulation, which is now available to the machine as a new model. If the simulation cannot be run on the machine controller of a machine, it is run externally on edge or in the cloud. The new, extended model of the first AI is then verified and refined using real tests 40 in a real DoE (machine learning). This means that the result: “Component good” or “Component bad because . . . ” must now be fed back to the model in the dialogue in order to refine the model of the first AI.

A second AI is now used for this purpose, which allows the operator 20 to provide the required information (data) in a simple dialogue via a user interface UI. This second AI is embodied as a software communication robot, e.g. as a chatbot, which preferably “elicits” the required data from the operator 20 in the simplest form using 3D graphical support.

An example of an illustrative dialogue in the DoE sequence could be as follows:
Machine: “I have changed a process parameter. Is the component quality still good?”
Operator: “No”
Machine: “Which quality feature is no longer fulfilled?”
Operator: “The component has sink marks and is no longer completely filled”
Machine: “Show me the position of the sink marks in the 3D component image”.
The Machine shows the 3D image of the (plastics) component to be produced in a 3D visualisation. The operator 20 marks the positions of the sink marks on the 3D image directly in the graphic and confirms this in the dialogue.
Machine: “Thank you very much. Now show me where the component is not completely filled?”
Here too, the operator 20 shows the chatbot CB, the second AI, the fault locations in the 3D image.

This is a simple example that shows the dialogue between the second AI and the operator 20. This dialogue can take place in a chat window using keyboard input as the user interface UI, but can of course also be conducted using voice input.

In conjunction with the preferably 3D visualisation and/or also supported by graphic selection symbols, simple communication with the machine is thus also possible for semi-skilled operators.

The first AI model is trained or refined using the process information obtained by the second AI (machine learning). Once this process is complete, the optimised process AI can be activated.

It has proved advantageous to carry out the simulation for producing the at least one component on the machine in step 100 as a filling simulation for filling a mould cavity of an injection mould on an injection moulding machine. The filling simulation makes it clearest where problems can arise during the manufacturing process, for example when larger cross-sections alternate with thin-walled cross-sections on the moulded part. In addition, the filling simulation also makes it clear at which point in time material is in which position. In the filling simulation, the material properties make it easy to recognise whether an original virgin material or a recycled material is being used.

To generate the statistical DoE matrix, it is preferable to use expert knowledge 120 that would be available to a trained user as an expert Exp. The expert knowledge also includes the knowledge available in the literature. It also includes knowledge about machines and machine data MD or materials and their properties. The expert knowledge can be specified to the machine or the machine can be trained with it by means of various process sequences, including sequences according to the disclosure.

The information from the expert knowledge is preferably categorised and differentiated according to classes, wherein the classes contain the following information in particular:
classes of machine properties,
classes of material properties,
component classes,
mould classes for injection moulds,
filling time classes in the injection process for producing the component,
flow path to wall thickness ratios in the component,
plastics classes,
material classes.

Classification is preferably carried out interactively with the operator 20 by the software communication robot CB (chatbot) on the basis of these criteria in order to have relevant information from the expert knowledge 120 available and accessible for calculation.

As further information, the machine and the artificial intelligence can also be provided with machine data and/or material information of the material to be processed by the operator 20 and/or selected as information from the expert knowledge 120. This material information is then used for the simulation so that the process parameter dataset PPD is calculated taking this information into account. Material information can be current information obtained for the particular batch, which is made available to the method by material analyses on site in individual cases.

To speed up the evaluation process, especially during the interactive evaluation in step 112a,a three-dimensional representation of the component in the form of a 3D graphic 122 has proved useful. The operator 20 can then view the component on a display device formed as an operator interface Ul and mark the points of the component that they wish to evaluate accordingly. This information can then be evaluated by the software communication robot CB and processed accordingly. This procedure makes it easier for the operator 20 to make a clear statement about where any problems on the component can be recognised.

The process model PM obtained by the method can be used not only for an initial setting dataset or for a process parameter dataset PPD. If deviations occur during operation of the machine, the machine can use the information available to it from the process model PM to monitor whether manufacture is still feasible. The process sequence with simulations of the DoE matrix and with real evaluated ones provides a process model PM, which is shown quite clearly in FIG. 1 by a closed frame, showing where and under which conditions operation of the machine is possible. The operation of the machine with the process parameter dataset PPD at the determined operating point AP is, specifically, part of a process window PF—shown as a dashed line in FIG. 1—within the process model PM. As long as the manufacture of components with a process parameter dataset PPD takes place within the process window PF, recalculation or intervention of the machine or the machine controller 10 is not necessary. The machine can continue to be operated in accordance with step 116. However, if the process window is left, readjustment may be necessary.

When leaving the process window PF, the machine can first issue a warning message. This can be within the scope of the query 114. However, it can also check whether the originally determined process window PF is still applicable following instructions from the operator 20 or automatically based on the information now available to it. It is conceivable, for example, that the material quality has changed in the meantime due to a different batch or that process parameters can no longer be applied in the same way due to a corresponding operating time. In this case, the determination of a process window can be carried out again, preferably starting from step 106 of generating the design of experiments (DoE) matrix, but at the latest starting from step 110 of verifying the remaining variations of process parameters.

During operation, the process can now always be kept within the PF process window, which delivers the best possible component quality.

If irregularities still occur, the process model PM can be expanded and refined at any time using the dialogue described above by way of example (machine learning).

Parts of the dialogue can of course also be automated. For example, quality parameters such as the geometry of the component can be evaluated by means of downstream optical inspection systems and fed to the model by means of a standardised, digital dialogue. The same applies also to other quality parameters such as weight, surface, colour, strength, temperature, etc.

It is also possible to obtain some of this information from downstream processes, e.g. during testing in the downstream quality assurance department, and feed it into the machine learning process in a digital dialogue.

Ideally, in larger injection moulding companies, data from similar or identical machines on which similar or identical processes with materials of the same or similar material class are running can be preferably “collected”. This “on edge” summarisation and evaluation of all machine model data makes it possible to generate even better algorithms and therefore an even better AI model as part of federated learning. The operator can thus gain access to swarm knowledge. System operators can roll out an algorithm generated in this way from their “model factory” to other production sites and maintain the same high product quality worldwide while also protecting their know-how.

FIG. 2 schematically shows the interaction of the process elements. As indicated in step 100, simulation data SD is first provided or used to simulate the manufacture of components (FIG. 2, top right). This can take place on the machine controller 10 or, as shown in FIG. 2, also on edge or in the cloud. As a rule, this creates an initial process image with an initial DoE evaluated via the simulation, which is used to create training data for a base model BM.

This base model BM (step 104) is thus available for use by the machine controller 10 or a simulation computer and thus the AI model.

If a base model BM does not yet exist, a design of experiments DoE is developed with the help of expert knowledge 120, which was made available to the machine by an expert Exp, and is input or loaded into the machine controller 10 or trained through process sequences, in order to make the base model BM available to the AI model. However, the expert knowledge can also be involved in the very first creation of a DoE matrix.

Through process tests, i.e. initially virtual tests, a machine-specific process model PM is created from the base model BM. This is done in the first step 108 by simulating a DoE matrix while reducing the variation possibilities of process parameters. Starting from the base model, a DoE reduced by simulation is provided, simulated, evaluated and the base model is refined using the training data obtained in this way. The DoE matrix is thus reduced by the base model. This reduced DoE matrix serves as the basis for further process tests. At the same time, the reduced DoE matrix is simulated on edge/in the cloud and the base model BM is retrained and made available to the controller.

In addition, real tests 40 are carried out with a further reduced DoE matrix in step 110 and actual process values are determined, which are made available to the process model PM. Based on the DoE matrix, the component evaluations and the actual process values, a process model PM is trained starting from a base model BM (the base model serves here as the basis for the process model).

In order to also qualitatively assess the results, a desired process parameter dataset PPD for a working point AP, there is carried out an evaluation EB of the components manufactured in this way. This can be done interactively (step 112a) with the operator 20 by the additional AI communicating with the operator, which is done via the chatbot CB. The chatbot CB can derive analysis and action recommendations from this and make these available to the operator 20. As explained above, this can also be supported by a 3D graphic 122 of the component. Alternatively, quality monitoring can also be performed automatically (step 112b) and the evaluation results provided. The chatbot is supported in its function by expert knowledge 120. The components can be evaluated in two phases: Once during the tests, and then during the productive process, i.e. during the manufacture of components in the manufacturing process.

The resulting evaluation in turn allows the second AI to re-evaluate the DoE matrix in order to improve the process model PM. This in turn influences the process parameter dataset PPD for the operating point AP as well as the process window PF, within which the machine can reliably produce good components. The improved process model PM can then be used to calculate a new process parameter set PPD for the operating point AP.

The machine manufacturer is also interested in the machine operator providing at least extracts of the algorithms generated “on edge” to the cloud of the machine manufacturer. The latter collects the extracts of the algorithms from as many machine operators (customers) as possible, i.e. the content released by customers, compares them and thus refines the generation of the base models (Deep learning).

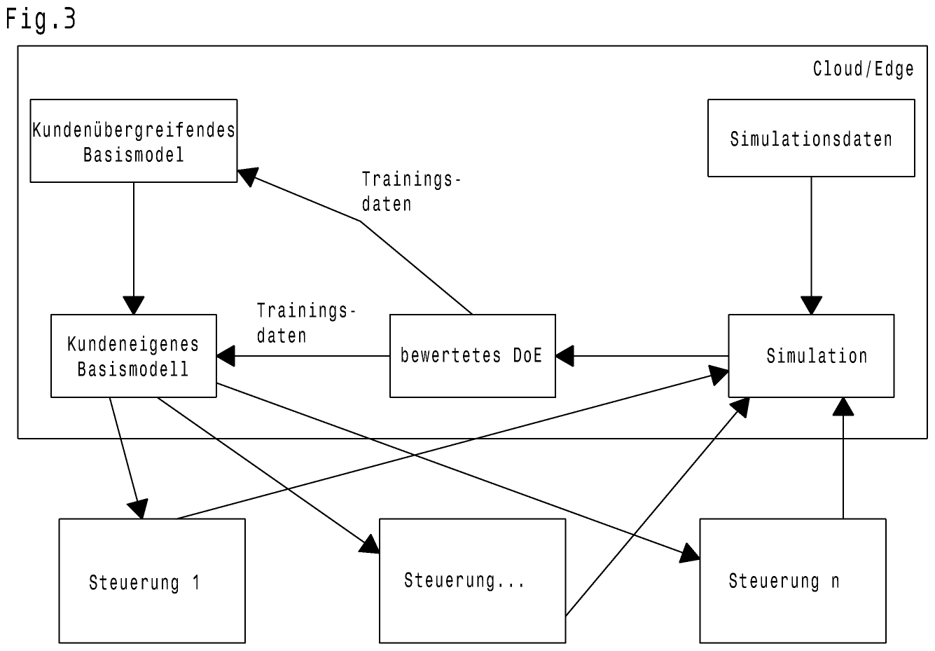

This is explained in greater detail by the diagram in FIG. 3. The upper part of the Figure shows a cloud/edge solution. In this region, as explained with regard to FIG. 2, a simulation and an evaluation of a DoE matrix is carried out in order to obtain training data for a base model, in this case a customer's own base model. The customer can provide this customer-specific base model to the controllers of various of their own machines, such as the machine controller 10 in FIG. 2. Each controller 1 . . . controller n can be associated with at least one machine. Data is returned to the simulation via the controllers-also as in FIG. 2-in order to improve/reduce the DoE matrix and refine the base model. So far, this diagram describes a customised on edge solution.

The results of the evaluated DoE matrix, e.g. training data, can also be made available, at least in part, to a cross-customer base model, which is maintained by the machine manufacturer, for example. This collects this training data from as many machine operators as possible in order to further improve the generation of the base models.

The advantages mentioned with regard to the method also apply to a machine controller 10 for a machine for processing plastics and other plastifiable materials, provided that the machine controller 10 is set up, configured and/or constructed to carry out the method accordingly.

Similarly, the advantages according to the method arise when using a computer program product with a program code that is stored on a computer-readable medium, so that the method can be carried out using the program code.

It goes without saying that this description may be subject to a wide range of modifications, changes and adaptations that are within the scope of equivalents to the appended claims.

1. A computer-implemented method for controlling processes on at least one machine for processing plastics and other plastifiable materials, wherein the method comprises the steps of
a. carrying out a simulation for producing at least one component on the machine while at least one of generating simulation datasets or reading in simulation datasets generated during the production of at least one component on the machine and containing simulations necessary for a production of the component, wherein the simulation datasets relate at least to a mould contour of the component and/or material properties of at least one material to be processed,
b. determining a process image for operating the machine with an idealised operating point based on the simulation datasets,
c. generating a Design of Experiments matrix, hereinafter DoE matrix, starting from the idealised operating point, wherein the DoE matrix comprises a set of possible combinations of parameter values for operating the machine,
d. iteratively simulating the DoE matrix with calculation and determination of remaining variations of process parameters with which the machine can be operated in reality, wherein the possible combinations of parameter values of the DoE matrix are reduced and a process model for the machine trained by the simulation is generated, with which a component can be produced on the machine,
e. verifying remaining variations of process parameters by carrying out real tests, in which components are produced and evaluated on the machine, to generate a process parameter dataset for operating the machine at an operating point and then operating the machine with the process parameter dataset at the operating point,
wherein
an operator with a software communication robot is provided and configured for interactively communicating with an operator, which software communication robot is configured for recognising at least one of a voice input or a text input or a gesture input by an operator and for outputting or displaying information about the operating state of the machine or the state of the component, wherein the software communication robot is connected to a control device for data communication in order to control the machine on the basis of the at least one of the voice input or the text input or the gesture input recognised by the software communication robot, and
wherein steps a to e comprise at least two artificial intelligences which interact with one another.

2. The method in accordance with claim 1 wherein in step e an automated dialogue takes place with a control device which communicates with at least one evaluation system for evaluating the component.

3. The method in accordance with claim 1, wherein the method is carried out on an injection moulding machine or on a machine for additive manufacturing of components.

4. The method in accordance with claim 1, wherein the simulation for producing the at least one component on the machine is a filling simulation for filling a mould cavity of an injection mould on an injection moulding machine.

5. The method in accordance with claim 1, wherein information from an expert knowledge is used to generate the DoE matrix and is categorised and distinguishable by classes according to at least one of the following criteria, comprising
classes of machine properties,
classes of material properties,
component classes,
mould classes for injection moulding tools,
filling time classes in the injection process for manufacturing the component,
flow path to wall thickness ratios in the component,
plastics classes,
material classes,
wherein the software communication robot (CB) with the operator performs a classification based on these criteria to make relevant information from the expert knowledge available for calculation.

6. The method in accordance with claim 1, wherein material information of the at least one material to be processed is specified to the machine as further information by the operator or is selected as information from the expert knowledge, which is used for the simulation, and wherein the process parameter dataset is calculated taking into account the material information.

7. The method in accordance with claim 1, wherein during the communication of the operator with the software communication robot, the component is displayed three-dimensionally and at least a part of the component can be marked by the operator in the display for communication with the software communication robot.

8. The method in accordance with claim 1, wherein the operation of the machine with the process parameter dataset at the operating point is part of a process window within the process model, wherein operation of the machine within the process window permits production of components, and wherein operation of the machine is monitored by a machine controller for leaving the process window.

9. The method in accordance with claim 8, wherein when the process window is left, the method is carried out again, starting from the step of generating the DoE matrix or starting from a verification of the remaining variations of the process parameters.

10. The method in accordance with claim 1, wherein it is carried out on a plurality of machines and at least one of
respective process models trained through simulation or
respectively generated process parameter datasets or
respective operating points
are used to form clusters according to at least one of the same or similar machine configurations, the same processes or the same or similar materials to be processed and these clusters are evaluated in order to operate machines in a process model adapted as a result of results of the evaluation using federated learning.

11. The method in accordance with claim 10, further comprising the steps of:
comparing the results of the evaluation at least partially with each other and determining comparison results,
refining the process models required for the method based on the comparison results.

12. A machine controller for a machine for processing plastics and other plastifiable masses, wherein the machine controller is, configured for carrying out the method in accordance with claims 1.

13. A computer program product comprising a program code stored on a computer-readable medium for carrying out the method in accordance with claims 1.

14. The method in accordance with claim 1, wherein software communication robot is a chatbot.
